(19) United States
(12) Patent Application Publication
(10) Pub. No.: US 2007/0108576 A1
(43) Pub. Date: May 17, 2007

(54) Packaging structure of RSMMC memory card

(76) Inventors: Chin-Chun Liu, Pingjhen City (TW); Shih-Tung Liu, Gongguan Township (TW)

Correspondence Address: Dykema Gossett, PLLC, Suite 300 West, 1300 I Street, N.W., Washington, DC, 20005-3306, US

(21) Appl. No.: 11/272,065

(22) Filed: Nov. 14, 2005

(51) Int. Cl. H01L 23/02

(52) U.S. Cl. 257/679

(57) ABSTRACT

The present invention provides a packaging structure of a RSMMC memory card. The packaging structure comprises a substrate having a plurality of integrated circuit (IC) devices and passive devices located therein. A frame engaging with the substrate is surrounded with the IC devices and the passive devices. A metal cover having an insulating layer is engaged with the frame to form a thin layer of structure. A plurality of fixed plates bending downward are formed around a circumferential area of the metal cover, and a protruding plate and fixing slots are formed on one end of the pre-selected fixed plates bending outward. The frame and the metal cover are integrated together to form a sealed structure. The integrated circuit devices and the passive devices are located within the space of the frame to form a RSMMC memory card package.

### BACKGROUND OF THE INVENTION

1. Field of Invention

The present invention relates generally to a packaging structure of memory card package. More particularly, the present invention relates to an improved packaging structure of RSMMC memory card.

2. Description of the Related Art

The conventional package structure of RSMMC memory card is showed in FIG. 1 and FIG. 2. The package structure comprises an electrical circuit board 10 and a plastic cover 20. The electrical circuit board 10 further comprises passive devices and various integrated circuit (IC) devices, such as flash IC. A plurality of golden fingers are formed on a back surface of the electrical circuit board 10 and are utilized to electrically connect to other electrical devices. The plastic cover 20 is formed into a L-shaped plastic cover and is utilized to cover the electrical circuit board 10 in order to seal all the IC devices and the passive devices. Therefore, package of RSMMC memory card is formed.

The conventional packaging structure of RSMMC memory card must utilize the plastic cover 20 to seal the whole packaging structure. The fabricating process of the plastic cover 20 involving a projecting shaped must be formed so that a space can be formed in between as shown in FIGS. 1 & 2. As result the thickness of the plastic cover 20 must be maintained to a required thickness so that the structure is strong enough to subject any pressure. However, when the thickness of the plastic cover 20 is increased to thicken its thickness, the space within the plastic cover is thus reduced. As a result, less IC devices can be located inside the substrate. As a matter fact, most fabricators utilized those expansive, very thin and small in size of IC devices in order to accommodate the limited space within the packaging structure. Thus, the manufacturing cost of the package of the memory card is increased. Furthermore, those expansive IC devices are not reliable, and the cost of the package structure of the RSMMC memory card is thus increased, its competition in the market is therefore reduced.

### SUMMARY OF INVENTION

It is an object of the present invention to provide a packaging structure of a RSMMC memory card. More particularly, the present invention relates to an improved packaging structure of RSMMC memory card. The present invent provide an improved design of packaging structure that has enough space to accommodate different types of IC devices and passive devices can be installed therein. It is another object of the present invention to provide a packaging structure of the RSMMC memory card comprising reliable IC devices and the packaging structure can be fabricated with low cost in order to increase its competition in the market. The packaging structure of the present invention comprises a substrate having a plurality of IC devices and passive devices located therein. A frame integrated with the substrate is surrounded with the IC devices and the passive devices. A metal cover having an insulating layer formed on a top portion of the metal cover. The metal cover is covered the frame and the substrate to form a sealed structure. A plurality of fixed plates bending downward are formed around a circumferential area of the metal cover, and a protruding block and fixing slots are formed on pre-selected protruding plate of the frame. The protruding bock and the fixing slots are utilized to engage the frame onto the metal cover in order to form a RSMMC packaging structure. The IC devices and the passive devices are located within the space of the frame and are protected by the metal cover.

Both the foregoing general description and the following detailed description are exemplary and explanatory only and are restrictive of the invention, as claimed.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIG. 1 illustrates a 3-D view of a conventional packaging structure of RSMMC memory card.

FIG. 2 shows a partial cross-sectional view of the conventional packaging structure of RSMMC memory card.

FIG. 3 is a 3-D assembled view of a packaging structure of RSMMC memory card in accordance with a preferred example of the present invention.

FIG. 4 is another 3-D view of a completed assembled structure of a packaging structure of RSMMC memory card in accordance with the preferred example of the present invention.

FIG. 5 is a partial cross-sectional view of the assembled structure of the RSMMC memory card in FIG. 4

FIG. 6 is another 3-D view of assembled view of a packaging structure of RSMMC memory card in accordance with a preferred example of the present invention.

FIG. 7 is a 3-D view of a coating layer onto a back surface of a substrate of a preferred example of the present invention.

FIG. 8 is a partial cross-sectional view of a back surface of the coating layer of the substrate in FIG. 7.

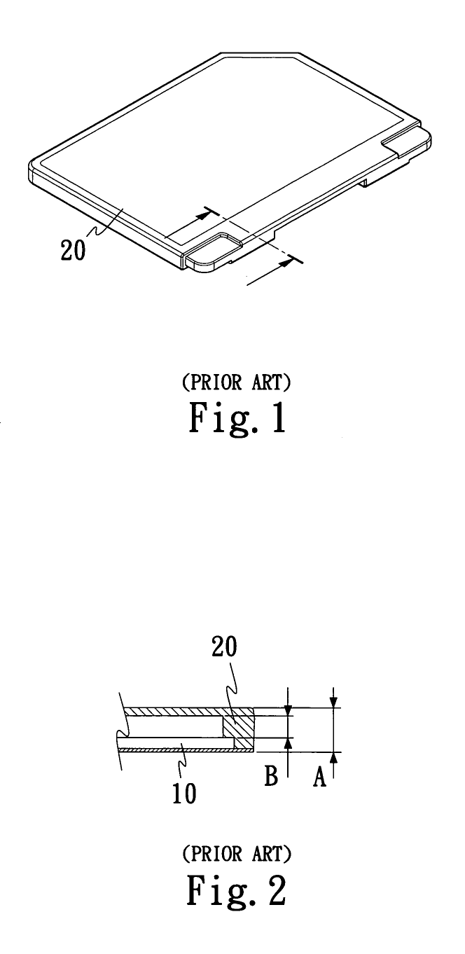

### DESCRIPTION OF THE PREFERRED EMBODIMENTS

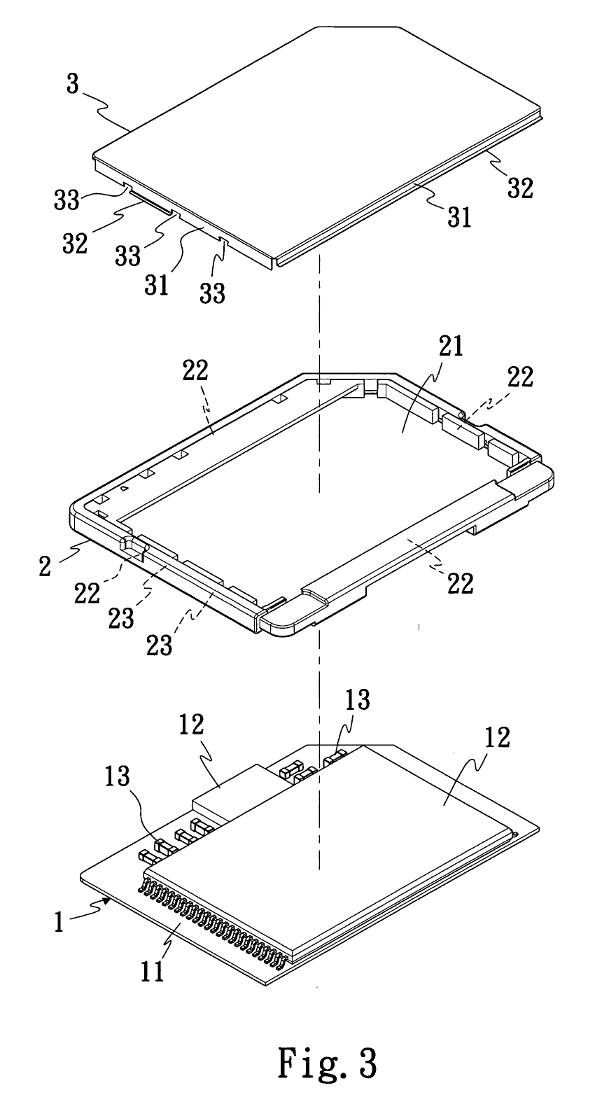

Refer to FIG. 3, the present invention provides a packaging structure of RSMMC memory card, the packaging structure comprises a substrate 1, a frame 2 and a metal cover 3. Wherein the substrate 1, as shown in FIG. 3, is a circuit board consisting required circuits formed on its platform. An inner platform 11 comprising various type of integrated circuit (IC) devices 12 that are required by a memory card, such as the control chip device and flash IC chip, as well as other passive devices 13. A plurality of golden pins 15 are formed on an outer platform 14. The golden pins 15 are utilized to electrical connect to other electrical products.

The frame 2, as shown in FIG. 3, is a square shaped plastic frame for integrating the substrate 1 and is surrounded by the various types of IC devices 12 and the passive devices 13. A space 21 is formed in a middle portion of the frame 2 and is utilized to locate the devices 12 and the passive devices 13. At least one L-shaped slot 22 is formed on a pre-selected strip block locating on a circumferential area of the space 21. The L-shaped slot 22 is utilized to integrate the frame 2 to the metal cover 3. Four strip-shaped blocks can be formed around the circumferential area of the space 21, and every strip-shaped block has a L-shaped slot 22. A protruding block 23 is formed outside a pre-set strip-shaped block and is utilized to integrate with the metal cover 3.

The metal cover 3, as shown in FIG. 3, is utilized to cover the substrate 1 locating on a top surface of the frame 2 so that a sealed thin layer of metal device is formed. This thin layer of metal device is approximately 0.05 mm thick and an insulating layer is formed onto its surface. A plurality of fixed plates 31 are formed around a circumferential area of a bottom portion of the metal cover 3 and are bended downward. A L-shaped protruding plate 32 is formed on one end of the pre-selected fixed plate 31 bended outward. Fixing slots 33 are formed correspondingly to the position of the protruding block 23 along the pre-selected fixed plates 31.

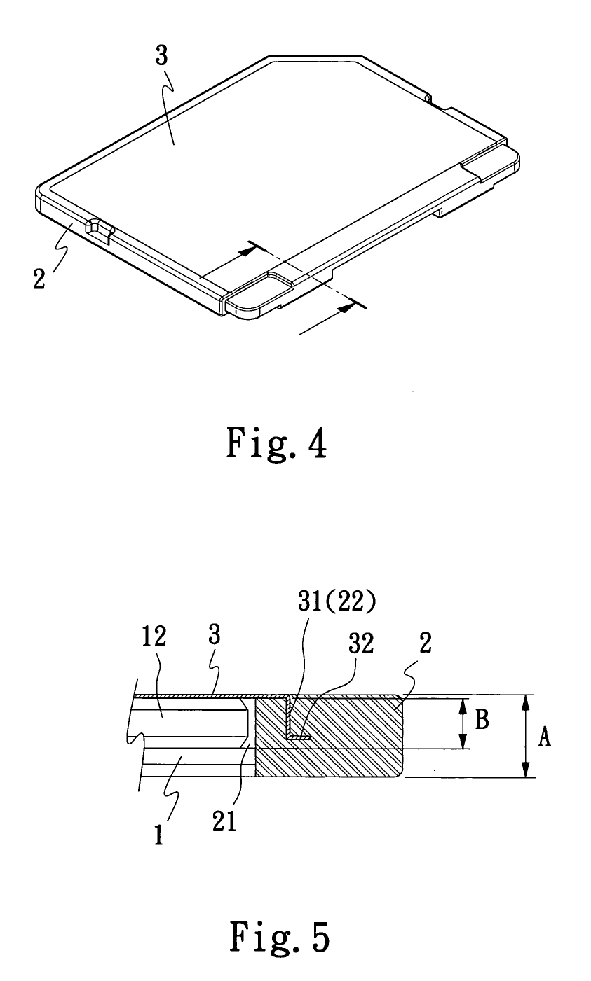

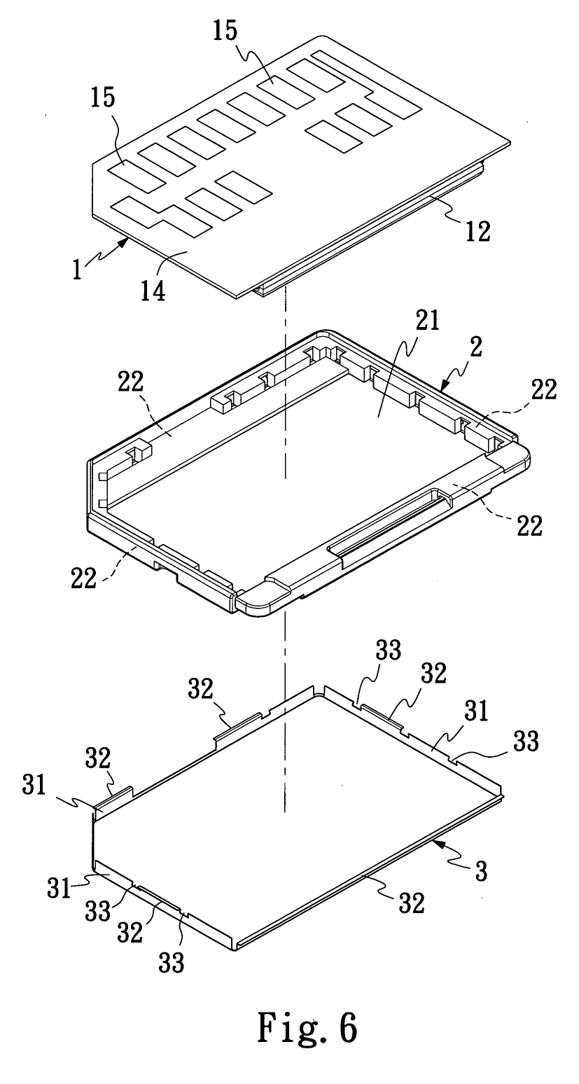

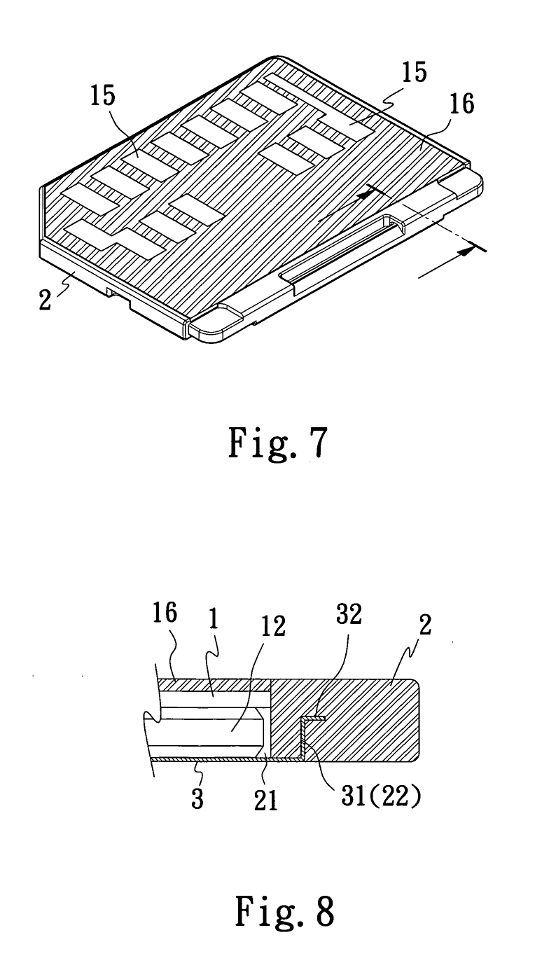

The frame 2 is directly engaged with the metal cover 3 to form a projecting-shaped structure as shown in FIG. 4 and FIG. 5. The L-shaped protruding plate 32 and the fixing slots 33 locating around the metal cover 3 are utilized to engage with the frame 2. (The protruding portions such as the L-shaped slot 22 and the protruding block 23 are engaged together to form a fixed structure). The substrate 1 is engaged into the gap 22 of the frame 2 so that the metal cover 3 so that the metal cover 3 covers and seals the IC devices 12 and the passive devices 13 locating within the substrate 1. A coating layer 16 is formed on an outer surface 14 of the substrate 1 to fill up the gap inside the substrate as shown in FIG. 7 and FIG. 8. The golden fingers 15 are separated away from other structures. Thus, a packaging of RSMMC memory card structure is formed.

The present invention provides a design of a packaging structure of RSMMC memory card. The frame 2 and the metal cover 3 can be pre-assembled with the substrate 1 to form a sealed structure. The metal cover 3 comprises enough ductile materials that it can form into a very thin layer structure with a thickness approximately 0.05 mm. The present invention provides an improvement on the design of the frame 2 and the metal cover 3 and its assembled structure. The improved design of the RSMMC memory card can be thus increased its spacious size inside the frame 2, such as the space 21, in order to locate any various IC devices 12 without failing the thickness requirement of the RSMMC memory card as shown in FIG. 5. The IC devices 12 can be control chip device and flash IC chip, as well as other passive devices 13. The improved packaging structure of RSMMC memory card of the present invention provides enough space 21 within the substrate 1 so that the fabricators or designers can choose various IC devices that are reliable with low cost so that the fabrication on the package can be thus reduced. Once there is no limitation of choosing different IC devices, the package structure of the RSMMC can be varied in accordance with the needs of the market or the customers. Thus, its marketing competition can be increased.

The forgoing is considered illustrative of the principles of the invention. As variations and related embodiments may occur to those skilled in the art, it is to be appreciated the invention, and all suitable modifications and equivalents, are only to be limited by the scope of the claims following hereinafter.

What is claimed is:

1. A packaging structure of RSMMC memory card, comprising:
a substrate having a plurality of integrated circuit devices and passive devices located an internal board of the substrate, and a plurality of golden fingers are formed on an outer board of the substrate;
a frame is a plastic frame that is integrated with the substrate and is surrounded with the integrated circuit devices and the passive devices, wherein a space is formed in a middle part of the frame; and
a metal cover having an insulating layer formed on a top portion of the metal cover, wherein a plurality of fixed plates bending downward are formed around a circumferential area of the metal cover, a protruding plate is formed on one end of a pre-selected fixed plate bending outward, the protruding plate and the fixed plates are utilized to integrate the frame to the metal cover to form a sealed structure so that the substrate is integrated into a bottom part and the space of the frame, the metal cover seals all the integrated circuit devices and the passive devices of the frame to form a RSMMC memory card package.

2. The packaging structure of claim 1, wherein at least one L-shaped slot is formed on a pre-selected strip-shaped block of the frame and is utilized to integrate directly with the metal cover.

3. The packaging structure of claim 1, wherein fixing slots are formed on pre-selected fixed plates of metal cover so that a protruding block is formed outside a pre-selected strip-shaped block of the frame and is utilized to integrate with the fixing slots of the metal cover.

4. The packaging structure of the claim 1, wherein a coating layer formed on a back surface of the substrate is utilized to fill up the space of the frame and to separate the structure of the golden fingers away from other devices.
